(19) United States
(12) Patent Application Publication
(10) Pub. No.: US 2013/0087093 A1
(43) Pub. Date: Apr. 11, 2013

(54) APPARATUS AND METHOD FOR HVPE PROCESSING USING A PLASMA

(71) Applicants: Donald J.K. Olgado, Palo Alto, CA (US); Yuriy Melnik, Santa Clara, CA (US); Hiroji Hanawa, Sunnyvale, CA (US); Karl M. Brown, Santa Clara, CA (US); Son T. Nguyen, San Jose, CA (US); Kevin S. Griffin, Livermore, CA (US)

(72) Inventors: Donald J.K. Olgado, Palo Alto, CA (US); Yuriy Melnik, Santa Clara, CA (US); Hiroji Hanawa, Sunnyvale, CA (US); Karl M. Brown, Santa Clara, CA (US); Son T. Nguyen, San Jose, CA (US); Kevin S. Griffin, Livermore, CA (US)

(73) Assignee: Applied Materials, Inc., Santa Clara, CA (US)

(21) Appl. No.: 13/456,547

(22) Filed: Apr. 26, 2012

Related U.S. Application Data
(60) Provisional application No. 61/545,267, filed on Oct. 10, 2011.

(51) Int. Cl. C30B 25/10; C30B 25/02

(52) U.S. Cl. 117/103; 118/723 E

(57) ABSTRACT

Embodiments of the present invention generally relate to a hydride vapor phase epitaxy (HVPE) apparatus that utilizes a high temperature gas distribution device and plasma generation to form an activated precursor gas used to rapidly form a high quality compound nitride layer on a surface of a substrate. In one embodiment, plasma is formed from a nitrogen containing precursor within a gas distribution device prior to injection into a processing region of the HVPE apparatus. In another embodiment, plasma is formed from a nitrogen containing precursor within the processing region by using the gas distribution device as an electrode for forming the plasma in the processing region. In each embodiment, a second precursor gas may be separately introduced into the processing region of the HVPE apparatus through the gas distribution device without mixing with the nitrogen containing precursor prior to entering the processing region.

### CROSS-REFERENCE TO RELATED APPLICATIONS

This application claims benefit of Provisional Patent Application Ser. No. 61/545,267 filed Oct. 10, 2011, which is herein incorporated by reference.

### BACKGROUND OF THE INVENTION

1. Field of the Invention

Embodiments disclosed herein generally relate to apparatus and methods for hydride vapor phase epitaxy (HVPE).

2. Description of the Related Art

Group III-V films are finding greater importance in the development and fabrication of a variety of semiconductor devices, such as short wavelength light emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, such as Group II-VI materials.

One method for depositing Group-III nitrides is hydride vapor phase epitaxy (HVPE), which may be distinguished from other methods of depositing Group-III nitrides, such as metal organic chemical vapor deposition (MOCVD), due to the significantly lower ratio of nitrogen containing precursor to Group-III metal precursor needed to deposit a Group-III metal nitride layer on a substrate. In a conventional HVPE apparatus, a hydride gas, such as HCl, reacts with the Group-III metal to form a precursor gas, which then reacts with a nitrogen precursor to form the Group-III metal nitride layer on the substrate. These chemical vapor deposition type methods are generally performed in a reactor having a temperature controlled environment to assure the stability of a first precursor gas, which contains at least one Group III element, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer on the substrate surface. The quality of the film depends in part upon deposition uniformity which, in turn, depends upon uniform mixing of the precursors across the substrate. However, it is difficult to maintain the temperature of both the processing region and the gas distribution device since condensation of the precursors may form if the temperature is too low and high particle buildup may occur if the temperature is too high.

In addition, to maintain a desired processing gas concentration and fluid dynamic conditions in the chamber, it is common to continuously flow the precursors into the processing region of the chamber and out an exhaust port of the chamber. Thus, unreacted gases are exhausted from the chamber and sent to a waste collection system or scrubber along with reaction byproducts. In general, the precursor gases are often costly, and thus, the amount of unreacted process gases that are wasted greatly affects the cost-of ownership of the deposition system. These factors are important since they directly affect the cost to produce an electronic device and, thus, a device manufacturer's competitiveness in the marketplace.

Therefore, there is a need for an improved deposition apparatus and process that can provide a high deposition rate, with consistent film quality over larger substrates and deposition areas, while minimizing waste of costly processing gases.

### SUMMARY OF THE INVENTION

Embodiments of the present invention generally relate to a hydride vapor phase epitaxy (HVPE) apparatus that utilizes a high temperature gas distribution device and plasma generation to form an activated precursor gas used to rapidly form a high quality compound nitride layer on a surface of a substrate.

In one embodiment of the present invention, a processing apparatus comprises a chamber body comprising one or more walls defining a processing region, a substrate support disposed in the processing region, and a gas distribution showerhead comprising silicon carbide and disposed above the substrate support. The gas distribution showerhead comprises a plenum having an inlet for coupling to a first precursor delivery source and one or more electrodes for coupling to a power source. The processing apparatus further comprises a plasma generation apparatus for providing a second precursor.

In another embodiment, a processing apparatus comprises a chamber body comprising one or more walls defining a processing region, a substrate support disposed in the processing region, and a gas distribution showerhead disposed above the substrate support. The gas distribution showerhead comprises a first plenum having an inlet for coupling to a first precursor delivery source, one or more electrodes for coupling to a power source, and a second plenum for coupling to a plasma generation apparatus for providing a second precursor.

In yet another embodiment, a method of depositing a layer on one or more substrates comprises forming nitrogen radicals from a nitrogen containing gas, forming a plasma over a heated source material to form a metal halide gas, and flowing the metal halide gas into a processing region of a processing chamber to mix with the nitrogen radicals.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of an HVPE processing chamber according to one embodiment.

FIG. 2 is a schematic sectional view of a showerhead for use in the HVPE processing chamber according to one embodiment.

FIG. 3 is a schematic sectional view of a showerhead for use in the HVPE processing chamber according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to a hydride vapor phase epitaxy (HVPE) apparatus that utilizes a high temperature gas distribution device and plasma generation to form an activated precursor gas used to rapidly form a high quality compound nitride layer on a surface of a substrate. Many commercial electronic devices, such as power transistors, as well as optical and optoelectronic devices, such as light-emitting diodes (LEDs), may be fabricated from layers of compound nitride films, which include film stacks that contain group III-nitride films. In one embodiment, a plasma is formed from a nitrogen containing precursor within a gas distribution device prior to injection into a processing region of the HVPE apparatus, in which one or more substrates are disposed. In another embodiment, plasma is formed from a nitrogen containing precursor within the processing region by use of a gas distribution device that has an electrode disposed therein to form a plasma in the processing region. In yet another embodiment, plasma is formed from a nitrogen containing precursor using a remote plasma source prior to introduction into the gas distribution device. In each embodiment, a second precursor gas (or plasma formed therefrom) may be separately introduced into the processing region of the HVPE apparatus through the gas distribution device without mixing with the nitrogen containing precursor (or plasma formed therefrom) prior to entering the processing region.

Delivering an activated nitrogen gas species into the processing region to react with the second precursor (such as a metal halide containing gas) improves the efficiency and deposition reaction kinetics, particularly at low processing pressures and flows (e.g., less than 1 Torr and 1 slm), which results in reduced processing time and improved film quality. In addition, introduction of the more reactive gas species provides more efficient reaction and use of the nitrogen containing precursor, which results in less waste of the often costly nitrogen containing precursor in the form of unreacted gas exhausted from the apparatus. In certain embodiments of the present invention, the gas distribution device is constructed of materials to allow higher temperature processing than gas distribution devices constructed of conventional materials (e.g., brazed stainless steel) in order avoid unwanted deposition within the HVPE apparatus and, in particular, the gas distribution device itself, particularly at high processing pressures and flows (e.g., greater than 0.5 atm and 1 slm), which are beneficial for increasing the deposition rate.

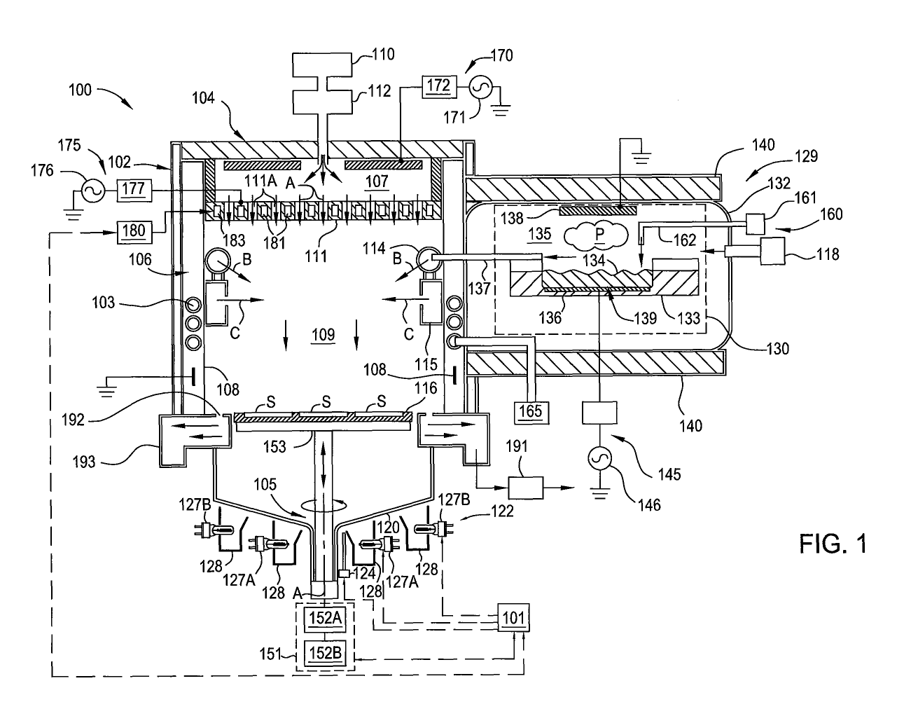

FIG. 1 is a schematic sectional view of an HVPE apparatus 100 according to one embodiment of the invention. The HVPE apparatus 100 includes a chamber 102, a chamber lid assembly 104, one or more precursor generation regions 129, a lamp assembly 122, a lower dome 120, a lift assembly 105 and a controller 101. The chamber lid assembly 104 generally comprises a gas distribution showerhead 111, which is disposed within an opening in the walls 106 of the chamber 102, and a gas source 110. A processing gas delivered from the gas source 110 flows into the processing region 109 of the chamber 102 through a plurality of gas passages 111A formed in the gas distribution showerhead 111. The gas source 110 may be adapted to deliver a nitrogen containing compound to the processing region 109. In one example, the gas source 110 is adapted to deliver the nitrogen containing precursor gas, which may include a gas comprising ammonia (NH₃) and/or hydrazine (N₂H₄). An inert gas, such as helium or diatomic nitrogen, may be introduced into the processing region 109 as well either through the gas distribution showerhead 111, or through the walls 106 of the chamber 102 (e.g., reference label “C”). An energy source 112 may be disposed between the gas source 110 and the gas distribution showerhead 111. The energy source 112 may comprise a remote plasma source (RPS), a heater, or other similar type device that is adapted to form radicals and/or disassociate the gas from the gas source 110, so that the nitrogen from the nitrogen containing gas is more reactive. The gas source 110 generally introduces the precursor gas, which may be excited by the energy source 112, into a plenum 107 formed within the showerhead 111. The excited gases, or radicals, are then distributed into the processing region 109 through the gas passages 111A.

In one example, it has been found that in conventional, thermal HVPE systems using ammonia (NH₃), a very small percentage (e.g., 3-5%) of the ammonia reacts with a metal halide containing precursor gas to form desirable nitride layer on a surface of a substrate. In contrast, it has been found that exciting the ammonia gas in a plasma drastically increases its reactivity, and thus increases the amount of nitrogen from the ammonia gas that will react with the metal halide containing precursor. Thus, more efficient utilization of the costly ammonia precursor may be realized by exciting the ammonia to form nitrogen radicals and/or ions prior to introduction to the processing region 109 of the chamber 102.

The showerhead 111 further includes one or more temperature control channels 181 formed therein and coupled with a heat exchanging system 180 for flowing a heat exchanging fluid through the showerhead 111 to help regulate the temperature of the showerhead 111. Suitable heat exchanging fluids include, but are not limited to, water, water-based ethylene glycol mixtures, a perfluoropolyether (e.g., GALDEN® fluid), oil-based thermal transfer fluids, or similar fluids.

The showerhead 111 further includes one or more thermocouples 183 disposed therein for detecting the temperature of the showerhead 111 during processing. The controller 101 may receive input from the thermocouples 183 and control the flow and/or temperature of heat exchanging fluid from the heat exchanging system 180 to control the temperature of the showerhead during processing 111. The showerhead 111 may be constructed of a material that is able to withstand high processing temperatures and is resistant to the precursor gases used. For example, the showerhead 111 may be fabricated from silicon carbide (SiC), tungsten (W), tantalum (Ta), tungsten carbide (WC), boron nitride (BN), tungsten lanthanum (WL), or the like. Fabricating the showerhead 111 from such materials allows the face of the showerhead 111 to be maintained at a much higher temperature (e.g., 500-550° C.) than conventional showerhead materials such as brazed stainless steel showerheads. It has been found that maintaining the showerhead 111 at such elevated temperatures, during high pressure (greater than 0.5 atm), high flow (greater that 1 slm) processes increases the deposition efficiency, while avoiding unwanted deposition within the chamber 102 and on the showerhead 111.

In the chamber 102, heating of one or more substrates “S” disposed in the processing region 109 is accomplished by directly or indirectly heating the substrates “S” using a lamp assembly 122 that is disposed below a susceptor 153 and the lower dome 120, which is fabricated from an optically transparent material (e.g., quartz dome). Lamps 127A, 127B in the lamp assembly 122 deliver heat to a substrate carrier 116 and/or the susceptor 153 that then deliver the received heat to the one or more substrates “S” disposed thereon. The lamp assembly 122, which may include arrays of lamps 127A, 127B and reflectors 128, is generally the main source of heat for the processing chamber 102. While shown and described as a lamp assembly 122, it is to be understood that other heating sources may be used.

Additional heating of the processing chamber 102 may be accomplished by use of a heater assembly 103 (e.g., cartridge heater) embedded within the walls 106 of the chamber 102. The heater assembly 103 may include a series of tubes that are coupled to a fluid type heat exchanging device 165. A thermocouple 108 may be used to measure the temperature of the walls 106 of processing chamber, and one or more pyrometers 124 may be used to monitor the temperature of the carrier 116 and substrates “S”. Output from the thermocouple and the one or more pyrometers 124 are fed back to a controller 101, so that the controller 101 can control the output of the heater assembly 103 and the arrays of lamps 127A, 127B based upon the received temperature readings.

The lift assembly 105, which includes an actuator assembly 151, is configured to position and rotate the susceptor 153, substrate carrier 116 and substrates “S” to help control the temperature uniformity of the substrates “S” during processing. A vertical lift actuator 152A and a rotation actuator 152B, which are contained in the actuator assembly 151, are used to position and rotate the substrates “S” in the processing region 109, and are controlled by the controller 101.

During processing, regions of the chamber 102 may be maintained at different temperatures to form a thermal gradient that can provide a gas buoyancy type mixing effect using the controller 101 and the various temperature control mechanisms within the apparatus 100. For example, the processing gases (e.g., nitrogen based gas) delivered from the gas source 110 are introduced through the gas distribution showerhead 111 at a temperature between about 450° C. and about 550° C. by controlling the lamp assembly 122, thermocouples 183, and heat exchange system 180. The chamber walls 106 may be controlled to have a temperature of about 600° C. to about 700° C. using the lamp assembly 122, thermocouples 108, and/or heater assembly 103. The susceptor 153 may be controlled to have a temperature of about 1050° C. to about 1150° C. using the lamp assembly 122 and the pyrometers 124.

In one example, the GaN film is formed over one or more substrates “S” by a HVPE process at a susceptor 153 temperature between about 700° C. to about 1100° C. Thus, the temperature difference within the chamber 102 may permit the gas to rise within the chamber 102 as it is heated and then fall as it cools. The rising and falling of the gases (i.e., buoyancy effect) may cause the nitrogen containing precursor gas “A” and the activated precursor gas(es) “B” to mix. Additionally, the buoyancy effect may reduce the amount of gallium nitride or aluminum nitride that deposits on the walls 106 because of the mixing.

The one or more precursor generation regions 129 may be configured to form metal halide containing precursor gases, such as gallium and aluminum halide containing precursor gases. While reference will be made to two precursors herein, more or fewer precursors may be delivered. In one embodiment, the precursor delivered from the one or more precursor generation regions 129 comprises gallium, which is formed from a source material 134 that is in a liquid form. In another embodiment, the precursor delivered from the one or more precursor generation regions 129 comprises aluminum, which is present in the precursor generation region 129 in a solid form.

The precursor may be formed and delivered into the processing region 109 of the chamber 102 by flowing a reactive gas into the source processing region 135 of the precursor generation region 129 from a gas source 118, generating plasma over the source material 134 and then delivering the formed plasma activated metal halide gas from the source processing region 135 to the processing region 109 of the chamber 102 by use of a push gas (e.g., N₂, H₂, He, Ar). The activated precursor gas can be delivered from the source processing region 135 of the precursor generation region 129 to a precursor delivery gas distribution element 114 via a delivery tube 137 (see arrow “B”). A separate cleaning gas distribution element 115 may be used to deliver a cleaning gas “C”, such as a halogen gas (e.g., F₂, Cl₂), to the processing region 109 to remove any unwanted deposition on the chamber 102 process kit parts during one or more phases of the deposition process.

An exhaust plenum 193 is coupled to a chamber pump 191. The exhaust plenum 193 is disposed in the chamber 102 about the susceptor 153 to help direct exhaust gases from the chamber through exhaust ports 192 and out of the chamber 102.

In one embodiment of the HVPE apparatus 100, the precursor generation region 129 comprises a chamber 132, a plasma generation apparatus 130, a source material 134, a source assembly 145, a gas source 118, a feed material source 160 and a heater assembly 140. The chamber 132 generally comprises one or more walls that enclose a source processing region 135. The one or more walls generally comprise a material that is able to withstand the high processing temperatures typically used to form the plasma activated precursor gas, and also maintain their structural integrity when the processing pressure within the source processing region 135 is reduced to pressures as low as about 1 Torr by use of the chamber pump 191. Typical wall materials may include quartz, silicon carbide (SiC), boron nitride (BN), stainless steel, or other suitable material. In one configuration, the chamber pump 191 is coupled to the source processing region 135 through the delivery tube 137 and ports 192 formed in the exhaust plenum 193 found in the chamber 102.

As depicted in FIG. 1, the plasma generation apparatus 130 includes a crucible 133 that is configured to retain an amount of source material 134 (e.g., Ga, Al, In) that is disposed in a material collection region 139 formed in the crucible 133. An activated precursor gas is created by the formation of a plasma over the surface of the source material 134 using a process gas delivered from the gas source 118. The gas source 118 is generally configured to deliver one or more gases to the source processing region 135 of the chamber 132 to form the activated group-III metal halide precursor gas therein. The gas source 118 may be configured to deliver a halogen gas (e.g., Cl₂, F₂, I₂, Br₂), or hydrogen halides (e.g., HCl, HBr, HI), and a push gas (e.g., N₂, H₂, He, Ar) that are used to form the group-III metal halide precursor gas (e.g., GaClₓ, InClₓ, AlClₓ) and push the formed precursor gas into the processing region 109 of the chamber 102.

The plasma generation apparatus 130 may include capacitively coupled, or inductively coupled, DC, RF and/or microwave sources that are configured to deliver energy to the source material 134 and/or process gases disposed in the processing region 135 of the precursor generation region 129. In general, a plasma, which is a state of matter, is created by the delivery of electrical energy or electromagnetic waves (e.g., radio frequency waves, microwaves) to a process gas to cause it to at least partially breakdown to form ions, electrons and neutral particles (e.g., radicals). In one example, a plasma is created in the processing region 135 by the delivery electromagnetic waves from the source assembly 145 at frequencies less than about 100 gigahertz (GHz).

The crucible 133 generally comprises an electrically insulating material that can withstand the high processing temperatures that are commonly required to form a group-III metal halide precursor gas, and at least partially encloses the material collection region 139, which is adapted to hold the source material 134. In one configuration, the crucible 133 is formed from quartz, boron nitride (BN), silicon carbide (SiC), or combinations thereof.

An electrode 136 may be disposed within the material collection region 139, and electrically coupled to the source material 134, so that a plasma can be formed in the source processing region 135 over the surfaces of the source material 134. The plasma can be formed by delivering RF energy from a power source 146 to the electrode 136, thus RF biasing the source material 134 relative to a separate grounded electrode 138. The electrical energy delivered to the source material 134 causes the process gas(es) (e.g., halogen gases) disposed over the surfaces of the source material 134 to breakdown and form a plasma “P” (FIG. 1). The formed plasma enhances the formation and activity of the created group-III metal halide precursor gas, which is formed by the interaction of the plasma activated process gas(es). To assure that the source material 134 is in a desired physical state, such as a liquid or a solid, during the group-III metal halide precursor gas formation process, a heater assembly 140 (e.g., resistive heating elements, lamps) may be used to heat the source material 134 disposed in the material collection region 139 to a desired temperature.

Since the formation of the group-III metal halide precursor gas depletes the amount of source material 134 found in the crucible 133, it is desirable to assure that the amount of source material 134 disposed in the material collection region 139 does not run out during processing. Therefore, a feed material source 160 may be used to assure that a desired amount of the source material is always disposed in the material collection region 139 of the crucible 133. The feed material source 160 generally comprises a delivery assembly 161 and a delivery tube 162 that is adapted to deliver an amount of the source material 134 to the source material collection region 139 of the crucible 133. The delivery assembly 161 will generally include a source material retaining region (not shown) that is adapted to retain and then deliver a desired amount of the source material 134 to the source material collection region 139 by use of a pressurized gas source (not shown) or mechanical metering pump (not shown).

During processing, a first precursor gas from the gas source 110 and a second precursor gas from the one or more precursor generation regions 129 are both delivered to the processing region 109 of the chamber 102, so that the interacting gases can form a layer having a desirable composition on the one or more substrates “S” disposed in the processing region 109. As previously discussed the gas source 110 may provide a nitrogen containing precursor gas, such as ammonia (NH₃) or hydrazine (N₂H₄) to an energy source 112 (e.g., remote plasma source (RPS)) to form nitrogen radicals for introducing into the processing region 109, through the showerhead 111. The introduction of the formed nitrogen radicals from the first precursor gas into the processing region 109 provides more efficient interaction with the second precursor gas from the precursor generation regions 129.

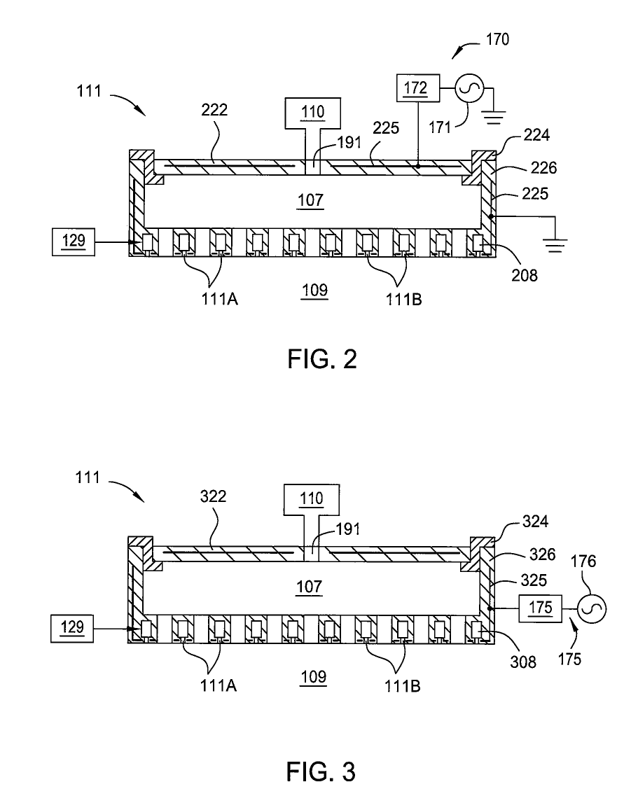

FIG. 2 is a schematic view of the showerhead 111 according to another embodiment. The showerhead 111 includes an upper plate 222, a lower plate 226, and an insulator 224 disposed between the upper plate 222 and the lower plate 226. The upper plate 222, insulator 224, and lower plate 226 define the plenum 107. In one embodiment, the upper and lower plates 222, 226 are both made of a metallic material resistant to high temperature processing, such as tungsten (W), tantalum (Ta), tungsten carbide (WC), boron nitride (BN), tungsten lanthanum (WL), or the like. In one embodiment, the upper plate 222 and/or the lower plate 226 may be made of silicon carbide (SiC) having a metallic electrode 225 disposed therein. Fabricating the showerhead 111 from such materials allows the face of the showerhead 111 to be maintained at a much higher temperature (e.g., 500-550° C.) than conventional showerhead materials such as showerheads that are constructed from stainless steel by use of one or more brazing processes. It is believed that the use of a showerhead 111 that has CiC containing surfaces that receive, or on which, a portion of a group III-nitride film will deposit, will provide a significant advantage over prior art showerhead materials (e.g., SST) due to the similar coefficient of thermal expansion (CTE) of the SiC material and the deposited group III nitride layers, such as gallium nitride (GaN). It has been found that maintaining the showerhead 111 at such elevated temperatures, during high pressure (greater than 0.5 atm) and high flow (greater that 1 slm) processes increases the deposition efficiency, while avoiding unwanted deposition within the chamber 102 and on the showerhead 111. A source assembly 170, which includes an RF power source 171 and an RF match 172, is electrically coupled to the upper plate 222 (or the electrode 225).

The lower plate 226 may further include another plenum 208 formed therein and coupled to the one or more precursor generation regions 129. A precursor from the precursor generation region 129 may be delivered into the plenum 208 and through gas passages 111B, formed in the lower plate 226, and into the processing region 109.

The gas source 110 is coupled to an inlet 191 of the plenum 107 in order to provide a nitrogen containing precursor gas, such as ammonia (NH₃), into the plenum 107. The source assembly 170 delivers RF power to the upper plate 222, which excites the gas flowing into the plenum 107 into a plasma. The excited gas (or nitrogen radicals) is then delivered into the processing region 109 through gas passages 111A formed through the lower plate 226. At the same time, the precursor (e.g., plasma activated metal halide gas) from the precursor generation region 129 is delivered into the processing region 109 either through the gas passages 111B in the showerhead 111 (FIG. 2) or through the delivery tube 137 and gas distribution element 114 (FIG. 1). Exciting the gas enhances its chemical activity (e.g., ability of gas atoms to react with other precursor gases), and due to the chamber gas delivery configuration, increases the interaction between the nitrogen containing precursor and the precursor gas from the precursor generation region 129, resulting in a more efficient deposition process occurring on the substrates “S” disposed in the processing region 109. In one example, a flow of about 600-800 sccm of ammonia (NH₃) and flow of about 50 sccm of gallium chloride is provided to the processing region 109 during processing to form a high quality gallium nitride (GaN) layer.

FIG. 3 is a schematic view of the showerhead 111 according to another embodiment. The showerhead 111 includes an upper plate 322, a lower plate 326, and an insulator 324 disposed between the upper plate 322 and the lower plate 326. The upper plate 322, insulator 324, and lower plate 326 define the plenum 107. In one embodiment, the upper and lower plates 322, 326 are both made of a metallic material resistant to high temperature processing, such as tungsten (W), tantalum (Ta), tungsten carbide (WC), boron nitride (BN), tungsten lanthanum (WL), or the like. In one embodiment, the upper plate 322 and/or the lower plate 326 may be made of silicon carbide (SiC). The lower plate 326 may be made of silicon carbide and have a metallic electrode 325 disposed therein. Fabricating the showerhead 111 from such materials allows the face of the showerhead 111 to be maintained at a much higher temperature (e.g., 500-550° C.) than conventional showerhead materials such as brazed stainless steel showerheads. It has been found that maintaining the showerhead 111 at such elevated temperatures, during high pressure (greater than 0.5 atm) and high flow (greater that 1 slm in the chamber) processes increases the deposition efficiency, while avoiding unwanted deposition within the chamber 102 and the showerhead 111. A source assembly 175, which includes an RF power source 176 and an RF match 177, is electrically coupled to the lower plate 326 (or the electrode 325).

In one example of a high pressure process, the power delivered to the electrode 325 is delivered at a frequency less than about 500 kHz and at a peak-to-peak voltage that is between about 5 and 20 kVolts. It is believed that the use of a plasma to enhance the deposition process can significantly reduce the amount of flow of certain precursor gases required to achieve a desired deposition rate. It has been found that the nitrogen precursor gas (NH₃) flow rate required to form a gallium nitride (GaN) layer, using a second gallium chloride (GaClₓ) precursor gas, can be significantly reduced, such as from about 30 slm to about 600 sccm when processing at a pressure of about 360 Torr and a substrate processing temperature of about 1050° C.

The lower plate 326 may further include another plenum 308 formed therein and coupled to the one or more precursor generation regions 129. A precursor from the precursor generation region 129 may be delivered into the plenum 308 and through gas passages 111B, formed in the lower plate 326, and into the processing region 109.

The gas source 110 may be coupled to an inlet 191 of the plenum 107 in order to provide a nitrogen containing precursor gas, such as ammonia (NH₃), into the plenum 107. RF power delivered to the lower plate 326 or electrode 325 from the source assembly 170 can be used to excite the gas(es) disposed in the processing region 109, to increase the activity of the gases disposed over the surface of the substrates “S,” and thus enhance the deposition process. In one embodiment of the activated precursor gas formation process, a gallium trichloride gas (GaCl₃), which is generated and delivered to the processing region 109 from a precursor generation region 129, is transformed into an activated gallium monochloride (GaCl) by use of the plasma formed in the processing region 109 by the source assembly 175.

### Low Pressure and Low Flow Processing

In an alternate processing configuration the processing region 109 of the processing chamber 102 is maintained at a low processing pressure (e.g., <100 mTorr), while a low precursor gas flow is delivered through the processing region, and plasma is formed therein to deposit a high quality group III nitride layer on one or more substrates. The low pressure and low flow processing regime, which tends to be a more diffusion limited processing regime, is useful to reduce the amount of process waste formed during the deposition process, and also improve one's ability to fine tune the deposited film's composition and electrical properties by controlling the flux of precursor gas(es) to the surface of the one or more substrates. In one example, a plasma enhanced HVPE deposition process is performed at a processing pressure of about 1-20 mTorr and at a flow rate of less than about 1000 sccm of a nitrogen precursor gas and/or a metal halide containing gas.

During processing, the formed plasma is used to excite one or more of precursor gases that are delivered to the substrates “S” disposed in the processing region 109. It is believed that a plasma enhanced low pressure and low flow process can be used to improve the cost of ownership of a group III nitride deposition process, since the plasma can be used to provide activated species (e.g., ions and neutral particles (e.g., radicals)) that have an enhanced reactivity. Thus, a higher percentage of the precursor gases that make it to the surface of the substrates will react and form a desirable layer thereon. A plasma enhanced low pressure and low flow process can also provide better control of the reaction rate and film quality of the deposited layer by separately controlling the flow of the active species (e.g., metal halide radicals, ammonia radicals) to the substrate surface by controlling the flow of one or more of the precursor gases delivered into the formed plasma and to the substrate surface.

In one configuration, as shown in FIGS. 1 and 3, the source assembly 175, which includes an RF power source 176 and an RF match 177, is electrically coupled to the lower plate 326 (or the electrode 325). In one example of a low pressure low flow process, the power delivered to the electrode 325 is delivered at a frequency less than about 13.56 MHz and at a peak-to-peak voltage that is between about 700 Volts and 1 kVolt, when the pressure in the processing region is between about 1 mTorr and 10 Torr. In this example, a flow of less than about 600 sccm of ammonia (NH₃) and flow of less than about 50 sccm of gallium chloride is provided to the processing region during processing to form a GaN layer.

While the foregoing is directed to embodiments of the present invention, other and further embodiments of the invention may be devised without departing from the basic scope thereof, and the scope thereof is determined by the claims that follow.

1. A processing apparatus, comprising:
a chamber body comprising one or more walls defining a processing region;
a substrate support disposed in the processing region;
a gas distribution showerhead comprising silicon carbide and disposed above the substrate support, wherein the gas distribution showerhead comprises:
a plenum having an inlet for coupling to a first precursor delivery source; and
one or more electrodes for coupling to a power source; and
a plasma generation apparatus coupled to the processing region for providing a second precursor.

2. The processing apparatus of claim 1, wherein the one or more electrodes comprises an upper electrode for coupling to the power source to form a plasma in the plenum.

3. The processing apparatus of claim 1, wherein the one or more electrodes comprises a lower electrode for coupling to the power source to form a plasma in the processing region.

4. The processing apparatus of claim 1, wherein the first precursor delivery source is configured to deliver a nitrogen containing precursor to the plenum.

5. The processing apparatus of claim 4, wherein the second precursor is a metal halide precursor.

6. A processing apparatus, comprising:
a chamber body comprising one or more walls defining a processing region;
a substrate support disposed in the processing region;
a gas distribution showerhead disposed above the substrate support, wherein the gas distribution showerhead comprises:
a first plenum having an inlet for coupling to a first precursor delivery source;
one or more electrodes for coupling to a power source; and
a second plenum for coupling to a plasma generation apparatus for providing a second precursor.

7. The processing apparatus of claim 6, wherein the gas distribution showerhead comprises silicon carbide.

8. The processing apparatus of claim 6, wherein the gas distribution showerhead comprises tungsten, tantalum, tungsten carbide, boron nitride, or tungsten lanthanum.

9. The processing apparatus of claim 6, wherein the one or more electrodes comprises an upper electrode for coupling to the power source to form a plasma in the plenum.

10. The processing apparatus of claim 6, wherein the one or more electrodes comprises a lower electrode for coupling to the power source to form a plasma in the processing region.

11. The processing apparatus of claim 6, wherein the first precursor delivery source is configured to deliver a nitrogen containing precursor to the first plenum.

12. The processing apparatus of claim 11, wherein the second precursor is a metal halide precursor.

13. A method of depositing a layer on one or more substrates, comprising:
forming nitrogen radicals from a nitrogen containing gas;
forming a plasma over a heated source material to form a metal halide gas; and
flowing the metal halide gas into a processing region of a processing chamber to mix with the nitrogen radicals.

14. The method of claim 13, further comprising flowing the nitrogen radicals into the processing region using a gas distribution showerhead.

15. The method of claim 14, further comprising flowing the metal halide gas into the processing region using the gas distribution showerhead.

16. The method of claim 14, further comprising forming the nitrogen radicals within a plenum disposed in the gas distribution showerhead.

17. The method of claim 14, further comprising maintaining a face of the gas distribution showerhead that is adjacent the processing region at a temperature between about 450 degrees C. and about 550 degrees C.
